(19) United States
(12) Patent Application Publication
(10) Pub. No.: US 2002/0051932 A1
(43) Pub. Date: May 2, 2002

(54) Photoresists for imaging with high energy radiation

(75) Inventors: Robert L. Brainard, Wayland, MA (US); Charles R. Szmanda, Westborough, MA (US)

Correspondence Address: EDWARDS & ANGELL, LLP, Dike, Bronstein, Roberts & Cushman, IP Group, P.O. Box 9169, Boston, MA, 02209, US

(73) Assignee: Shipley Company, L.L.C., Marlborough, MA

(21) Appl. No.: 09/870,243

(22) Filed: May 30, 2001

Related U.S. Application Data
(60) Provisional application No. 60/208,458, filed on May 31, 2000.

(51) Int. Cl. G03F 7/038; G03F 7/20; G03F 7/26

(52) U.S. Cl. 430/270.1; 430/296; 430/311; 430/325

(57) ABSTRACT

Photoresists are provided that are useful for imaging with high energy radiation sources, such as EUV, electron beam, ion beam and x-ray radiation. Resists of the invention can exhibit enhanced sensitivity and resolution upon such high energy imaging. In a first aspect, preferred resists of the invention can be characterized in part as having a high concentration of photoacid generator compound(s)relative to other resist components. In a further aspect, chemically-amplified positive-acting photoresists are provided that exhibit enhanced photoacid generation efficiency upon high energy exposures.

### BACKGROUND OF THE INVENTION

1. Field of the Invention

This invention relates to photoresists useful for imaging with high energy radiation sources, such as EUV, electron beam, ion beam and x-ray radiation. Resists of the invention can exhibit enhanced sensitivity and resolution upon such high energy imaging. Preferred resists of the invention can be characterized in part as having a high concentration of photoacid generator compound(s) relative to other resist components.

2. Background

Photoresists are photosensitive films for transfer of images to a substrate. They form negative or positive images. After coating a photoresist on a substrate, the coating is exposed through a patterned photomask to a source of activating energy such as ultraviolet light to form a latent image in the photoresist coating. The photomask has areas opaque and transparent to activating radiation that define an image desired to be transferred to the underlying substrate. A relief image is provided by development of the latent image pattern in the resist coating. The use of photoresists is generally described, for example, by Deforest, Photoresist Materials and Processes, McGraw Hill Book Company, New York (1975), and by Moreau, Semiconductor Lithography, Principals, Practices and Materials, Plenum Press, New York (1988).

Known photoresists can provide features having resolution and size sufficient for many existing commercial applications. However for many other applications, the need exists for new photoresists that can provide highly resolved images of submicron dimension. The electronics industry constantly demands means to produce ever-smaller dimension circuit patterns, e.g. to provide greater circuit density and enhanced device performance.

Consequently, interest has increased in photoresists that can be photoimaged with increasingly shorter wavelength radiation. For example, exposure with 193 nm (provided by an ArF exposure tool) can provide significantly enhanced resolution of small features, such as resist lines and spaces having a width of about 0.2 microns or less.

Even shorter wavelength (higher energy) radiation offers the potential for forming even smaller, resolved resist images. For instance, exposure with EUV (extreme ultraviolet), electron beam, ion beam and X-ray radiation offers the potential for forming extremely small, highly resolved resists images, which in turn can enable manufacture of microelectronic devices of higher circuit density and enhanced performance.

However, current resist compositions are typically not well-suited for such high energy exposure, i.e. those current resist materials do not provide acceptable lithographic performance upon exposure to high energy sources of EUV, electron beam, ion beam or X-ray.

It thus would be desirable to have photoresist compositions that could provide well resolved, small dimensions features. It would be particularly desirable to have photoresist compositions that could be effectively imaged with high energy radiation sources such as EUV, electron beam, ion beam and x-ray.

### SUMMARY OF THE INVENTION

We have now discovered new photoresist compositions that can be effectively imaged with high energy radiation, including EUV, electron beam and/or x-ray.

In a first aspect of the invention, photoresists of the invention can be characterized in part as having a high concentration of one or more photoacid generator compounds relative to the concentration of all other solid (i.e. all components except solvent carrier) components of the resist.

We surprisingly found that use of significantly increased levels of photoacid generator compound(s) can provide notably enhanced resolution of a resist image produced by exposure to high energy radiation e.g. radiation having a wavelength of less than about 160 nm, or more typically less than about 100 nm or radiation otherwise of high energy, such as EUV, electron beam, ion beam or x-ray.

For instance, we have found that resists that have a PAG concentration of greater than about 5 weight percent based on weight of total solids of a resist composition, more preferably a PAG concentration of at least about 6, 7, 8, 9, 10, 11, 12, 13, 14 or 15 weight percent based on weight of total solids of a resist composition, can be imaged with high radiation energy such as EUV, electron beam, ion beam or x-ray and produce dramatically enhanced resolved resist features, including features with reduced line edge roughness. Particularly preferred resists of the invention have a PAG concentration of from about 8 to 12 weight percent based on weight of total solids of the resist composition.

At lower energy exposures such as 193 nm or 248 nm, such high PAG concentrations would result in excessive PAG absorption and hence would be unacceptable. Accordingly, use of high PAG concentrations in accordance with the present invention is counterintuitive to conventional practice and provides clearly unexpected results.

In a further aspect of the invention, chemically-amplified positive-acting photoresists are provided that exhibit enhanced photoacid generation efficiency upon high energy exposures relative to prior copolymer resists, such as a prior resist that contains a deblocking resin that consists of repeat units of phenolic and alkyl acrylate units. Resins that are preferred for imparting such enhanced photogeneration efficiency are terpolymers (i.e. three distinct repeat units) or other higher order (i.e. four or more distinct repeat units) polymers that comprise phenolic repeat units, preferably repeat units of the following three types: i) phenol units, ii) phenyl units that do not contain hydroxy ring substituents, and iii) photo-acid labile units, particularly alkyl acrylate (which include alkyl methacrylate) units such as t-butyl acrylate.

We have unexpectedly found that resists that contain such phenolic terpolymers or other higher order resins can be highly sensitive (increased efficiency of photoacid generation) upon exposure to high energy radiation, e.g. radiation having a wavelength of less than about 160 nm, or more typically less than about 100 nm, or radiation otherwise of high energy, such as EUW, electron beam, ion beam or x-ray.

The increased efficiency of photoacid generation of such resists can be dramatic in comparison to the photoacid generation achieved using a lower energy radiation source such as 248 nm imaging radiation. Such efficiency of acid generation can be determined by any of a variety of methods, e.g. the Dill C-Parameter base titration method, or fluorescence and absorption methods.

As used herein, the term Dill C-Parameter means a first-order rate constant which is a measure of the rate at which photoacid is generated in a photoresist as a function of exposure. The Dill C-Parameter can be determined for a particular resist by preparing a plurality of resists, e.g. 3 to 6 resists, that are otherwise identical but contain 0 to 10 mole % base relative to PAG. The energy required to clear the resist after development (Eo) then can be determined. A plot of base concentration vs. energy to clear (Eo) yields a straight line. The slope of that line provides the Dill C-Parameter in units of reciprocal exposure (e.g. cm²/mJ or cm²/uC).

The invention also include resists that combine both aspects, i.e. resists that contain a high relative PAG concentration and a photoacid generating efficiency-enhancing phenolic terpolymer polymer or other higher order polymer. Such resist systems have provided particularly good lithographic results upon imagewise exposure to high energy radiation, such as radiation having a wavelength of less than about 160 nm, or more typically less than about 100 nm or radiation otherwise of high energy, such as EUV, electron beam, ion beam or x-ray.

Photoresists of the invention in general comprise a resin component and one or more photoacid generator compounds (“PAGs”).

A wide variety of photoacid generator compounds may be used in photoresists of the invention, including ionic PAG compounds such as onium salts, particularly sulfonium and iodonium compounds, as well as non-ionic PAG compounds such as imidosulfonates, N-sulfonyloxyimides, sulfonate esters, nitrobenzyl compounds, disulfone compounds, halogenated non-ionic compounds, and the like. Particularly preferred PAGs used in resists of the invention generate a halo-alkyl sulfonic acid such as a halo-C₁₋₁₆alkylsulfonic acid upon photoactivation, preferably a fluoro-C₁₋₁₆alkyl sulfonic acid, even more preferably a perfluoroC₁₋₁₆alkylsulfonic acid such as triflic acid and the like.

Preferred resists of the invention are chemically-amplified positive-acting resists, particularly positive-acting resists which undergo a photoacid-promoted deprotection reaction of acid labile groups of one or more composition components to render exposed regions of a coating layer of the resist more soluble in an aqueous developer than unexposed regions. Ester groups that contain a tertiary non-cyclic alkyl carbon or a tertiary alicyclic carbon covalently linked to the carboxyl oxygen of the ester are generally preferred photoacid-labile groups of resins employed in photoresists of the invention.

As discussed, particularly preferred positive-acting photoresists of the invention contain a high PAG concentration as disclosed herein and a resin that contains phenolic units.

Particularly preferred resins for use in resists of the invention include a phenolic resin that contains acid-labile groups that can provide a chemically amplified positive resist particularly suitable for imaging at 248 nm. Especially preferred resins of this class include polymers that contain polymerized units of a vinyl phenol and an alkyl acrylate, where the polymerized alkyl acrylate units can undergo a deblocking reaction in the presence of photoacid. Exemplary alkyl acrylates that can undergo a photoacid-induced deblocking reaction include e.g. t-butyl acrylate, t-butyl methacrylate, methyladamantyl acrylate, methyl adamantyl methacrylate, and other non-cyclic alkyl and alicyclic acrylates that can undergo a photoacid-induced reaction, such as polymers in U.S. Pat. Nos. 6,042,997 and 5,492,793, incorporated herein by reference.

As discussed, especially preferred are phenolic/acrylate resins for use in resists of the invention are terpolymers or other higher order polymers that contain polymerized units of a vinyl phenol, an optionally substituted vinyl phenyl (e.g. styrene) that does not contain a hydroxy or carboxy ring substituent, and an alkyl acrylate such as those deblocking groups described above, i.e. t-butyl acrylate, t-butyl methacrylate, methyladamantyl acrylate, methyl adamantyl methacrylate, and other non-cyclic alkyl and alicyclic acrylates. Such terpolymers have been disclosed in U.S. Pat. No. 6,042,997, incorporated herein by reference.

Still farther preferred resins for use in resists of the invention contain repeat units that comprise an acetal, ketal and/or an ortho-ester moiety that will react with photoacid, and preferably further comprise optionally aromatic repeat units such as phenyl or phenolic groups.

Generally most preferred resins for use in positive resists of the invention are terpolymers that contain: phenolic units; phenyl units (no hydroxy substituents); photoacid-labile alkyl acrylate (which includes methacrylate) units, such as polymers provided by polymerization of vinyl phenol, styrene and an alkyl acrylate such as t-butyl acrylate or t-butyl methacrylate. Preferred molar ratios of those units include from about 55 to about 80 mole percent of phenolic units, from about 10 to about 30 mole percent phenyl units, and from about 10 to 40 mole percent of alkyl acrylate units; more preferably from about 60 to about 75 mole percent of phenolic units, from about 15 to 25 mole percent of phenyl units, and from about 15 to 25 mole percent of alkyl acrylate units.

The invention also includes negative-acting resists, particularly negative-acting chemically amplified photoresists, i.e. negative-acting resist compositions which undergo a photoacid-promoted crosslinking reaction to render exposed regions of a coating layer of the resist less developer soluble than unexposed regions. These resists also comprise a high PAG concentration as discussed above.

Resists of the invention may comprise a single type of PAG compound, or a mixture of distinct PAGs, typically a mixture of 2 or 3 different PAGs, more typically a mixture that consists of a total of 2 distinct PAGs. Photoresists that contain such PAG mixtures potentially can exhibit even further enhanced lithographic performance.

The invention also provide methods for forming relief images of the photoresists of the invention, including methods for forming highly resolved patterned photoresist images (e.g. a patterned line having essentially vertical sidewalls) of sub-quarter micron dimensions or less, such as sub-0.2 or sub-0.1 micron dimensions.

The invention further provides articles of manufacture comprising substrates such as a microelectronic wafer or a flat panel display substrate having coated thereon the photoresists and relief images of the invention. Other aspects of the invention are disclosed infra.

### DETAILED DESCRIPTION OF THE INVENTION

As discussed above, resists of the invention may contains a variety of types of PAGs. In a first aspect of the invention, the one or more PAGs are present in relative high concentration as disclosed herein.

Onium salts are generally preferred PAGs for use in accordance with the invention. Examples of suitable onium salts include for example, halonium salts, quaternary ammonium, phosphonium and arsonium salts, aromatic sulfonium salts and sulfoxonium salts or selenium salts. Onium salts have been described in the literature such as in U.S. Pat. Nos. 4,442,197; 4,603,101; and 4,624,912.

Generally preferred onium salts include iodonium salt photoacid generators, such as those compounds disclosed in published European application 0 708 368 Al. Such salts include those represented by the following formula:

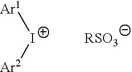

where Ar¹ and Ar² each independently represents a substituted or unsubstituted aryl group. A preferred example of the aryl group includes a C₆₋₁₄ monocyclic or a condensed ring aryl group such as phenyl or naphthyl. Preferred examples of the substituent on the aryl group include an alkyl group, a haloalkyl group, a cycloalkyl group, an aryl group, an alkoxy group, a nitro group, a carboxyl group, an alkoxycarbonyl group, a hydroxyl group, mercapto group, and a halogen atom.

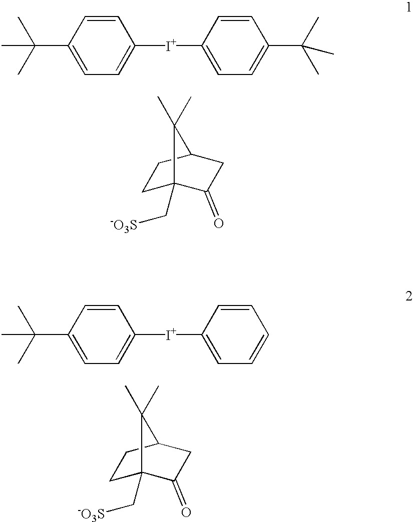

Such compounds can be prepared as disclosed in European Patent Application 96118111.2 (publication number 0783136), which details the synthesis of above PAG 1.

Also suitable are the above two iodonium compounds 1 and 2 complexed with anions other than the above-depicted camphorsulfonate groups. In particular, preferred anions include those of the formula RSO₃ where R is adamantane, alkyl (e.g. C₁₋₁₂ alkyl) and perfluoroalkyl such as perfluoro (C₁₋₁₂alkyl), particularly perfluoro counter anions of perfluorooctanesulfonate, perfluorononanesulfonate and the like.

Sulfonium salts are particularly suitable ionic photoacid generators for resists of the invention, such as compounds of the following formula:

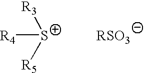

wherein R³, R⁴ and R⁵ each independently represents a substituted or unsubstituted alkyl group or aryl group such as phenyl. With regard to each of the above formulae, preferred examples of the substituted or unsubstituted alkyl group and aryl group include a C₆₋₁₄ aryl group, a C₁₋₅ alkyl group, and substituted derivatives thereof. Preferred examples of the substituent on the alkyl group include a C₁₋₈ alkoxy group, a C₁₋₈ alkyl group, nitro group, carboxyl group, hydroxyl group, and a halogen atom. Preferred examples of the substituent on the aryl group include a C₁₋₈ alkoxy group, carboxyl group, an alkoxycarbonyl group, a C₁₋₈ haloalkyl group, a C₅₋₈ cycloalkyl group and a C₁₋₈ alkylthio group. Two of R³, R⁴ and R⁵ may be connected to each other via its single bond or a substituent.

Additional preferred photoacid generators for use in resists of the invention include imidosulfonates such as compounds of the following formula:

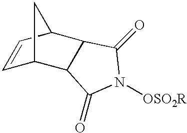

wherein R is camphor, adamantane, alkyl (e.g. C₁₋₁₆ alkyl) and perfluoroalkyl such as perfluoro(C₁₋₁₆alkyl), particularly perfluoro groups of perfluorooctanesulfonate, perfluorononanesulfonate and the like. Specifically preferred PAGs include N-[(perfluorooctanesulfonyl) oxy]-5-norbornene-2,3-dicarboximide and N-[(trifluoromethylsulfonyl) oxy]-5-norbornene-2,3-dicarboximide.

N-sulfonyloxyimide photoacid generators also are suitable for use in resist compositions of the invention, including those N-sulfonyloxyimides disclosed in International application WO94/10608, such as compounds of the following formula:

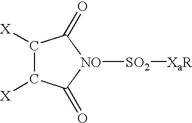

where the carbon atoms form a two carbon structure having a single, double or aromatic bond, or, alternatively, wherein they form a three carbon structure, that is, where the ring is instead a five member or six member ring; XaR is —CₙH₂ₙ₊₁ where n=1 to 8, —CₙF₂ₙ₊₁ where n=1 to 8, a camphor substituent, -2(9,10-diethoxyanthracene), —(CH₂)ₙ—Z or —(CF₂)ₙ—Z where n=1 to 4 and where Z is H, C₁₋₆ alkyl, a camphor substituent, -2-(9, 10-diethoxyanthracene, or aryl such as phenyl; X and Y (1) form a cyclic or polycyclic ring which may contain one or more hetero atoms, or (2) form a fused aromatic ring, or (3) may be independently hydrogen, alkyl or aryl, or (4) may be attached to another sulfonyloxyimide containing residue, or (5) may be attached to a polymer chain or backbone, or alternatively, form

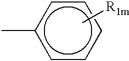

where R₁ is selected from the group consisting of H, acetyl, acetamido, alkyl having 1 to 4 carbons where m=1 to 3, NO₂ where m=1 to 2, F where m=1 to 5, Cl where m=1 to 2, CF₃ where m=1 to 2, and OCH₃ where m=1 to 2, and where m may otherwise be from 1 to 5, and combinations thereof, and where X and Y (1) form a cyclic or polycyclic ring which may contain one or more hetero atoms, (2) form a fused aromatic ring, (3) may be independently H, alkyl or aryl, (4) may be attached to another sulfonyloxyimide containing residue, or (5) may be attached to a polymeric chain or backbone.

Another class of photoacid generators suitable for use in resists of the invention include diazosulfonyl PAGs such as those disclosed in U.S. Pat. No. 5,558,976. Representative examples of these photoacid generators include:

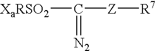

where XaR suitably is phenyl optionally substituted by halogen, C₁₋₆ alkyl, C₁₋₆ alkoxy, or C₁₋₆ haloalkyl, R⁷ is a straight-chain, branched or cyclic alkyl group having from 1 to 10 carbon atoms and Z is a sulfonyl group or a carbonyl group:

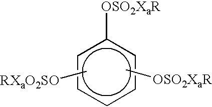

where R is as defined above; and

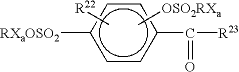

where R²² is hydrogen, hydroxyl or a group represented by the formula XₐRSO₂O— where XₐR is as defined above, and R²³ is a straight or branched alkyl group having from 1 to 5 carbon atoms or a group represented by the formula:

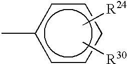

where R²⁴ and R³⁰ are independently a hydrogen atom, a halogen atom, a straight chain or branched alkyl group having 1-5 carbon atoms, a straight chain or branched alkoxy group having 1-5 carbon atoms, or a group of the formula:

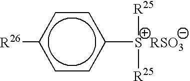

where each R²⁵ is independently a straight chain or branched alkyl group having 1-4 carbon atoms, a phenyl group, a substituted phenyl group or an aralkyl group; and R²⁶ is a hydrogen atom, a halogen atom or a straight-chain, branched or cyclic alkyl group having 1-6 carbon atoms.

Nitrobenzyl-based photoacid generators may also be employed as a PAG components of resists of the invention, including those disclosed in EPO published application No. EP 0 717 319 A1. Suitable nitrobenzyl-based compounds include those of the following formula:

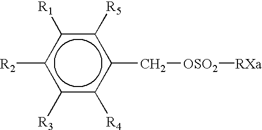

where each R₁, R₂ and R₃ are individually selected from the group consisting of hydrogen and lower alkyl group having from 1-4 carbon atoms; and R₄ and R₅ are individually selected from the group consisting of CF₃ and NO₂ and RXₐ, is optionally substituted carbocyclic aryl, particularly optionally substituted phenyl such as phenyl where the 2, 3, and 4 position substituents are selected from hydrogen and C₁₋₄ alkyl and where the 5 and 6 ring positions are selected from CF₃, NO₂ and SO3R′ where R′ of optionally substituted C₁₋₁₂ alkyl or aryl such as phenyl where such optional substituents may be C₁₋₄ alkyl, C₁₋₄ alkoxy, NO₂ or CF₃.

Disulfone derivatives are also suitable photoacid generators for use in resists of the invention. Suitable compounds are disclosed e.g. in published European application 0 708 368 A1. Such materials may be represented by the following formula:

Ar³—SO₂—SO₂—RX₂

wherein RXₐ is preferably as defined immediately above and Ar³ represents a substituted or unsubstituted aryl group. A preferred example of the aryl group includes a C₆₋₁₄ monocyclic or condensed-ring aryl group. Preferred examples of the substituent on the aryl group include an alkyl group, a haloalkyl group, a cycloalkyl group, an aryl group, an alkoxy group, nitro group, carboxyl group, an alkoxycarbonyl group, hydroxyl group, mercapto group, and halogen.

Halogenated non-ionic, photoacid generating compounds are also suitable for use in resists of the invention and include, for example, 1,1-bis[p-chlorophenyl]-2,2,2-trichloroethane (DDT); 1,1-bis[p-methoxyphenyl]-2,2,2-trichloroethane; 1,2,5,6,9,10-hexabromocyclodecane; 1,10-dibromodecane; 1,1-bis[p-chlorophenyl]-2,2-dichloroethane; 4,4-dichloro-2-(trichloromethyl) benzhydrol (Kelthane); hexachlorodimethyl sulfone; 2-chloro-6-(trichloromethyl) pyridine; o,o-diethyl-o-(3,5,6-trichloro-2-pyridyl) phosphorothionate; 1,2,3,4,5,6-hexachlorocyclohexane; N(1,1-bis[p-chlorophenyl]-2,2,2-trichloroethyl)acetamide; tris[2,3-dibromopropyl]isocyanurate; 2,2-bis[p-chlorophenyl]-1,1-dichloroethylene; tris[trichloromethyl]s-triazine; and their isomers, analogs, homologs, and residual compounds. Suitable photoacid generators are also disclosed in European Patent Application Nos. 0164248 and 0232972.

As referred to herein, the term “photoacid generator compound” is used in accordance with its art-recognized meaning and does not include photoactive compounds or “PACs”, particularly diazonaphthoquinone compounds, as have been employed in “conventional” (i.e. not chemically-amplified) positive-acting resists. As is recognized to those in the art, such “conventional” positive photoresists do not involve a deblocking reaction of a separate resin or separate dissolution inhibitor component to promote solubility differences between exposed and non-exposed areas of the resist coating layer.

The photoresists of the invention typically comprise a resin component and one or more photoacid generator compounds, wherein the photoacid generator compound(s) are present in relatively high concentration. Preferably, the photoacid generator compound(s) will be present in an amount of at least 5 weight percent based on total solids of a resist composition, more typically at least about 6, 7, 8, 9, 10, 11, 12, 13, 14 or 15 weight percent, based on total solids of a resist composition. It is generally not necessary to employ the photoacid generator compound(s) in an amount of greater than about 15, 16, 17, 18, 19 or 20 weight percent total solids of a resist composition. Particularly good lithographic results have been achieved where the photoacid generator compound(s) are present in amount of from about 8 to about 10, 11, 12, 13, 14 or 15 weight percent of total resist solids, or from about 11 to about 15 weight percent of total resist solids. As referred to herein, the term “total solids” refers to all resist components except the liquid solvent carrier.

The resin component of resists of the invention suitably has functional groups that impart alkaline aqueous developability to the resist composition. For example, preferred are resin binders that comprise polar functional groups such as hydroxyl or carboxylate. Preferably the resin binder is used in a resist composition in an amount sufficient to render the resist developable with an aqueous alkaline solution.

Phenolic-based resins are particularly suitable for resists of the invention. Preferred phenolic resins are poly (vinylphenols) which may be formed by block polymerization, emulsion polymerization or solution polymerization of the corresponding monomers in the presence of a catalyst. Vinylphenols useful for the production of polyvinyl phenol resins may be prepared, for example, by hydrolysis of commercially available coumarin or substituted coumarin, followed by decarboxylation of the resulting hydroxy cinnamic acids. Useful vinylphenols may also be prepared by dehydration of the corresponding hydroxy alkyl phenols or by decarboxylation of hydroxy cinnamic acids resulting from the reaction of substituted or nonsubstituted hydroxybenzaldehydes with malonic acid. Preferred polyvinylphenol resins prepared from such vinylphenols have a molecular weight range of from about 2,000 to about 60,000 daltons.

Additional suitable resins include those formed from bishydroxymethylated compounds, and block novolak resins. See U.S. Pat. Nos. 5,130,410 and 5,128,230 where such resins and use of same in photoresist compositions is disclosed. Additionally, two or more resin binders of similar or different compositions can be blended or combined together to give additive control of lithographic properties of a photoresist composition. For instance, blends of resins can be used to adjust photospeed and thermal properties and to control dissolution behavior of a resist in a developer.

As discussed, preferred are chemically amplified positive-acting resist. A number of such resist compositions have been described, e.g., in U.S. Pat. Nos. 4,968,581; 4,883,740; 4,810,613 and 4,491,628 and Canadian Patent Application 2,001,384, all of which are incorporated herein by reference for their teaching of making and using chemically amplified positive-acting resists.

Preferred chemically-amplified positive photoresist of the inventions comprise one or more photoacid generator compound in relative high concentration and a resin binder that comprises a copolymer containing both phenolic and non-phenolic units. For example, one preferred group of such copolymers has acid labile groups substantially, essentially or completely only on non-phenolic units of the copolymer, particularly alkylacrylate photoacid-labile groups, i.e. a phenolic-alkyl acrylate copolymer. One especially preferred copolymer binder has repeating units x and y of the following formula:

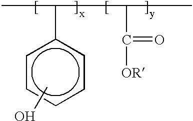

wherein the hydroxyl group be present at either the meta or para positions throughout the copolymer, and R′ is substituted or unsubstituted alkyl having 1 to about 18 carbon atoms, more typically 1 to about 6 to 8 carbon atoms. Tert-butyl is a generally preferred R′ group. An R′ group may be optionally substituted by e.g. one or more halogen (particularly F, Cl or Br), C₁₋₈ alkoxy, C₂₋₈ alkenyl, etc. The units x and y may be regularly alternating in the copolymer, or may be randomly interspersed through the polymer. Such copolymers can be readily formed. For example, for resins of the above formula, vinyl phenols and a substituted or unsubstituted alkyl acrylate such as t-butylacrylate and the like may be condensed under free radical conditions as known in the art. The substituted ester moiety, i.e. R′—O—C(=O)—, moiety of the acrylate units serves as the acid labile groups of the resin and will undergo photoacid induced cleavage upon exposure of a coating layer of a photoresist containing the resin. Preferably the copolymer will have a M_{w} of from about 1,500 to about 30,000, with a molecular weight distribution of about 3 or less, more preferably a molecular weight distribution of about 2 or less. Non-phenolic resins, e.g. a copolymer of an alkyl acrylate such as t-butylacrylate or t-butylmethacrylate and a vinyl alicyclic such as a vinyl norbomanyl or vinyl cyclohexanol compound, also may be used as a resin binder in compositions of the invention. Such copolymers also may be prepared by such free radical polymerization or other known procedures and suitably will have a M_{w} of from about 1,500 to about 30,000, and a molecular weight distribution of about 3 or less.

Another preferred resin component for a positive chemically amplified resist of the invention has phenolic and nonaromatic cyclic alcohol units, wherein at least of portion of the hydroxyl groups of the copolymer are bonded to acid labile groups. Preferred acid labile moieties are acetate groups including t-butyl acetate groups of the formula (CH₃)₃COC(O)CH₂—; oxycarbonyl groups such as t-butyl oxycarbonyl (t-Boc) groups of the formula (CH₃)₃CC(O)O—; and acetal and ketals. Chemically amplified positive-acting photoresists containing such a copolymer have been disclosed in U.S. Pat. No. 5,258,257 to Sinta et al.

Other preferred resins that have acid-labile deblocking groups for use in a positive-acting chemically-amplified photoresist of the invention have been disclosed in European Patent Application 0829766A2 of the Shipley Company (resins with acetal and ketal resins) and European Patent Application EP0783 136A2 of the Shipley Company (terpolymers and other copolymers including units of 1) styrene; 2) hydroxystyrene; and 3) acid labile groups, particularly alkyl acrylate acid labile groups such as t-butylacrylate or t-butylmethacrylate). In general, resins having a variety of acid labile groups will be suitable, such as acid sensitive esters, carbonates, ethers, imides, etc. The photoacid labile groups will more typically be pendant from a polymer backbone, although resins that have acid labile groups that are integral to the polymer backbone also may be employed.

Suitable polymers that are substantially or completely free of aromatic groups suitably contain acrylate units such as photoacid-labile acrylate units as may be provided by polymerization of methyladamanatylacrylate, methyladamanylmethacrylate, ethylfencylacrylate, ethylfencylmethacrylate, and the like; fused non-aromatic alicyclic groups such as may be provided by polymerization of a norbornene compound or other alicyclic compound having an endocyclic carbon-carbon double bond; an anhydride such as may be provided by polymerization of maleic anhydride; and the like.

Preferred negative-acting compositions of the invention comprise a mixture of materials that will cure, crosslink or harden upon exposure to acid, and a photoactive component of the invention.

Particularly preferred negative acting compositions comprise a resin such as a phenolic resin, a crosslinker component and one or more photoacid generator compounds in a high concentration as disclosed herein. Such compositions and the use thereof has been disclosed in European Patent Applications 0164248 and 0232972 and in U.S. Pat. No. 5,128,232 to Thackeray et al. Suitable phenolic resins for use as the resin binder component include novolaks and poly(vinylphenol)s such as those discussed above. Suitable crosslinkers include amine-based materials, including melamine, glycolurils, benzoguanamine-based materials and urea-based materials. Melamine-formaldehyde resins are generally most preferred. Such crosslinkers are commercially available, e.g. the melamine resins sold by American Cyanamid under the trade names Cymel 300, 301 and 303. Glycoluril resins are sold by American Cyanamid under trade names Cymel 1 1 70, 1171, 1172, urea-based resins are sold under the trade names of Beetle 60, 65 and 80, and benzoguanamine resins are sold under the trade names Cymel 1123 and 1125.

Photoresists of the invention also may contain other materials. For example, other optional additives include actinic and contrast dyes, anti-striation agents, plasticizers, speed enhancers, sensitizers, etc. Such optional additives typically will be present in minor concentration in a photoresist composition except for fillers and dyes which may be present in relatively large concentrations such as, e.g., in amounts of from 5 to 30 percent by weight of the total weight of a resist's dry components.

A preferred optional additive of resists of the invention is an added base, particularly tetrabutylammonium hydroxide (TBAH), especially a salt of TBAH such as TBAH lactate or acetate, which can enhance resolution of a developed resist relief image. The added base is suitably used in relatively small amounts, e.g. about 1 to 10 percent by weight relative to the PAG component, more typically 1 to about 5 weight percent. Other preferred basic additives include ammonium sulfonate salts such as piperidinium p-toluenesulfonate and dicyclohexylammonium p-toluenesulfonate; alkyl amines such as tripropylamine and dodecylamine; aryl amines such as diphenylamine, triphenylamine, aminophenol, 2-(4-aminophenyl)-2-(4-hydroxyphenyl) propane, etc.

The resin binder component of resists of the invention is typically used in an amount sufficient to render an exposed coating layer of the resist developable such as with an aqueous alkaline solution. More particularly, a resin binder will suitably comprise 50 to about 95 weight percent of total solids of the resist.

A resist of the invention can be suitably prepared as a coating composition by dissolving the components of the photoresist in a suitable solvent such as, e.g., a glycol ether such as 2-methoxyethyl ether (diglyme), ethylene glycol monomethyl ether, propylene glycol monomethyl ether; lactates such as ethyl lactate or methyl lactate, with ethyl lactate being preferred; propionates, particularly methyl propionate and ethyl propionate; a Cellosolve ester such as methyl Cellosolve acetate; an aromatic hydrocarbon such toluene or xylene; or a ketone such as methylethyl ketone, cyclohexanone and 2-heptanone. Typically the solids content of the photoresist varies between 5 and 35 percent by weight of the total weight of the photoresist composition.

Photoresists are typically applied on a substrate as a liquid coating composition such as by spin coating, dried by heating to remove solvent e.g. 80° C. to 160° C. preferably until the coating layer is tack free, exposed through a photomask to activating radiation, optionally post-exposure baked to create or enhance solubility differences between exposed and nonexposed regions of the resist coating layer, and then developed preferably with an aqueous alkaline developer to form a relief image

The substrate on which a resist of the invention is applied and processed suitably can be any substrate used in processes involving photoresists such as a microelectronic wafer. For example, the substrate can be a silicon, silicon dioxide or aluminum-aluminum oxide microelectronic wafer. Gallium arsenide, ceramic, quartz or copper substrates may also be employed. The substrate also can be chrome, e.g. chrome on glass substrate such as may be employed for photomask construction. Resists of the invention are particularly useful for processing photomask substrates.

Substrates used for liquid crystal display and other flat panel display applications are also suitably employed, e.g. glass substrates, indium tin oxide coated substrates and the like.

A liquid coating resist composition may be applied by any standard means such as spinning, dipping or roller coating.

The exposure energy may be x-ray, electron beam, extreme U.V. (i.e. EUV), ion beam radiation. EUV is generally recognized as having a wavelength of from 10-20 nm. X-ray exposure is recognized as about I nm, or about 4 to 50 angstroms. Resists of the invention are suitably imaged with radiation having a wavelength less than 160 nm, or less than about 100 nm.

After exposure through a photomask, the resist with latent patterned image is suitably subjected to a post-exposure bake, e.g. at temperatures of about 50° C. or greater, more specifically from about 100 to 160° C. For an acid-hardening negative-acting resist, a post-development bake may be employed if desired at temperatures of from about 100 to 150° C. for several minutes or longer to further cure the relief image formed upon development. After development and any post-development cure, the substrate surface bared by development may then be selectively processed, for example chemically etching or plating substrate areas bared of photoresist in accordance with procedures known in the art. Suitable etchants include a hydrofluoric acid etching solution and a plasma gas etch such as an oxygen plasma etch.

All documents mentioned herein are incorporated herein by reference. The following non-limiting examples are illustrative of the invention.

### EXAMPLES 1-4

### Photoresist Preparation and Lithographic Processing

### Example 1

A photoresist of the invention is prepared by mixing in ethyl lactate solvent: 1) a terpolymer that consists of 65 mole percent polymerized hydroxystyrene units, 15 mole percent styrene units, and 20 mole percent t-butylacrylate units; 2) a photoacid generator of di(t-butylphenyl)iodonium ortho-trifluoromethylsulfonate; and 3) tetrabutylammonium hydroxide lactate salt. The photoacid generator was present in an amount of 8 weight percent based on total weight of the terpolymer, photoacid generator and tetrabutylammonium hydroxide lactate salt. The resist is formulated at 5 weight percent solids.

The formulated resist composition is spin coated onto HMDS vapor primed silicon wafers and softbaked via a vacuum hotplate at 90° C. for 60 seconds to provide a coating layer of 0.1 micron thickness. The resist coating layer is exposed through a photomask to e-beam radiation. The exposed coating layers are post-exposure baked at 110° C. The coated wafers are then treated with 0.26 N aqueous tetrabutylammonium hydroxide solution to develop the imaged resist layer and provide a relief image. The developed relief image was 100 nm dense lines/spaces. Those 100 nm lines were well resolved and showed general absence of line edge roughness.

### Example 2

A photoresist of the invention is prepared by mixing in ethyl lactate solvent: 1) a terpolymer that consists of 65 mole percent polymerized hydroxystyrene units, 20 mole percent styrene units, and 15 mole percent t-butylacrylate units; 2) a photoacid generator of di(t-butylphenyl)iodonium ortho-trifluoromethylsulfonate; and 3) tetrabutylammonium hydroxide lactate salt. The photoacid generator was present in an amount of 8 weight percent based on total weight of the terpolymer, photoacid generator and tetrabutylammonium hydroxide lactate salt. The resist is formulated at 5 weight percent solids.

The formulated resist composition is spin coated onto HMDS vapor primed silicon wafers and softbaked via a vacuum hotplate at 90° C. for 60 seconds to provide a coating layer of 0.1 micron thickness The resist coating layer is exposed through a photomask to EUV radiation having a wavelength of about 15 nm. The exposed coating layers are post-exposure baked at 110° C. The coated wafers are then treated with 0.26 N aqueous tetrabutylammonium hydroxide solution to develop the imaged resist layer and provide a relief image.

### Example 3

A photoresist of the invention is prepared by mixing in ethyl lactate solvent: 1) a terpolymer that consists of 65 mole percent polymerized hydroxystyrene units, 20 mole percent styrene units, and 15 mole percent t-butylacrylate units; 2) a photoacid generator of di(t-butylphenyl)iodonium ortho-trifluoromethylsulfonate; and 3) tetrabutylammonium hydroxide lactate salt. The photoacid generator was present in an amount of 8 weight percent based on total weight of the terpolymer, photoacid generator and tetrabutylammoniium hydroxide lactate salt. The resist is formulated at 12.5 weight percent solids.

The formulated resist composition is spin coated onto HMDS vapor primed silicon wafers and softbaked via a vacuum hotplate at 90° C. for 60 seconds to provide a coating layer of 0.4 micron thickness. The resist coating layer is exposed through a photomask to EUV radiation having a wavelength of about 15 nm. The exposed coating layers are post-exposure baked at 110° C. The coated wafers are then treated with 0.26 N aqueous tetrabutylammonium hydroxide solution to develop the imaged resist layer and provide a relief image.

### Example 4

A photoresist of the invention is prepared by mixing in ethyl lactate solvent: 1) a terpolymer that consists of 72 mole percent polymerized hydroxystyrene units, 8 mole percent styrene units, and 20 mole percent t-butylacrylate units; 2) a photoacid generator of di(t-butylphenyl)iodonium ortho-trifluoromethylsulfonate; and 3) tetrabutylammonium hydroxide lactate salt. The photoacid generator was present in an amount of 8 weight percent based on total weight of the terpolymer, photoacid generator and tetrabutylammonium hydroxide lactate salt. The resist is formulated at 5 weight percent solids.

The formulated resist composition is spin coated onto HMDS vapor primed silicon wafers and softbaked via a vacuum hotplate at 90° C. for 60 seconds to provide a coating layer of 0.1 micron thickness. The resist coating layer is exposed through a photomask to e-beam radiation. The exposed coating layers are post-exposure baked at 110° C. The coated wafers are then treated with 0.26 N aqueous tetrabutylammonium hydroxide solution to develop the imaged resist layer and provide a relief image.

The foregoing description of the invention is merely illustrative thereof, and it is understood that variations and modifications can be effected without departing from the spirit or scope of the invention as set forth in the following claims.

What is claimed is:

1. A method for forming a photoresist relief image on a substrate comprising:
(a) applying a coating layer of a chemically-amplified positive photoresist composition on a substrate, the photoresist composition comprising a resin and one or more photoacid generator compounds, wherein the one or more photoacid generator compounds are present in a concentration of at least about 5 weight percent based on weight of total solids of the photoresist composition;
(b) exposing the photoresist coating layer to radiation having a wavelength of less than about 160 nm, or electron beam or ion beam radiation.

2. A method for forming a photoresist relief image on a substrate comprising:
(a) applying a coating layer of a chemically-amplified positive photoresist composition on a substrate, the photoresist composition comprising a phenolic resin and one or more photoacid generator compounds, the resin comprising at least three distinct repeat units;
(b) exposing the photoresist coating layer to radiation having a wavelength of less than about 160 nm, or electron beam or ion beam radiation.

3. The method of claim 2 wherein the one or more photoacid generator compounds are present in a concentration of at least about 5 weight percent based on weight of total solids of the photoresist composition.

4. The method of any one of claims 1 through 3 wherein the photoresist coating layer is exposed to EUV radiation.

5. The method of any one of claims 1 through 3 wherein the photoresist coating layer is exposed to electron beam or ion beam radiation.

6. The method of any one of claims 1 through 3 wherein the photoresist coating layer is exposed to x-ray radiation.

7. The method of any one of claims 1 through 6 wherein the one or more photoacid generator compounds are present in a concentration of at least about 6 weight percent based on weight of total solids of the photoresist composition.

8. The method of any one of claims 1 through 6 wherein the one or more photoacid generator compounds are present in a concentration of at least about 8, 9 or 10 weight percent based on weight of total solids of the photoresist composition.

9. The method of any one of claims 1 through 8 wherein the one or more photoacid generator compounds are present in a concentration up to about 12 weight percent based on weight of total solids of the photoresist composition.

10. The method of any one claims 1 through 6 wherein the one or more photoacid generator compounds are present in a concentration of from about 10 to about 15 weight percent of total solids of the photoresist composition.

11. The method of any one of claims 1 through 10 wherein the one or more photoacid generator compounds are ionic compounds.

12. The method of any one of claims 1 through 10 wherein the one or more photoacid generator compounds are non-ionic compounds.

13. The method of any one of claims 1 through 10 wherein the one or more photoacid generator compounds are onium compounds, imidosulfonate compounds, N-sulfonyloxyimide compounds, sulfonate ester compounds, nitrobenzyl compounds, disulfone compounds, and/or halogenated non-ionic compounds, or mixtures thereof.

14. The method of any one of claims 1 through 10 wherein the one or more photoacid generator compounds produce a halo-alkyl sulfonic acid upon exposure to activating radiation.

15. The method of any one of claims 1 through 10 wherein the one or more photoacid generator compounds produce a per-fluoro sulfonic acid upon exposure to activating radiation.

16. The method of any one of claims 1 through 15 wherein the resin comprises a polymer that contains phenolic units.

17. The method of any one of claims 1 through 15 wherein the resin comprises a polymer that contains phenolic and photoacid-labile alkyl acrylate units.

18. The method of any one of claims 1 through 15 wherein the resin comprises a polymer that contains 1) phenolic units, 2) phenyl units, and 3) photoacid-labile alkyl acrylate units.

19. The method of any one of claims 1 through 18 wherein the resin comprises a polymer that contains acetal, ketal or ortho ester groups.

20. A chemically-amplified positive photoresist composition comprising a resin and one or more photoacid generator compounds, wherein the one or more photoacid generator compounds are present in a concentration of at least about or greater than 5 weight percent based on weight of total solids of the photoresist composition, and the photoresist imageable with radiation having a wavelength of less than 100 nm, or electron beam or ion beam radiation.

21. A chemically-amplified positive photoresist composition on a substrate, the photoresist composition comprising a phenolic resin and one or more photoacid generator compounds, the resin comprising at least three distinct repeat units, the photoresist coating layer exhibiting, upon exposure to radiation having a wavelength of less than about 160 nm, or electron beam or ion beam radiation, enhanced photoacid generation efficiency as determined by Dill C-Parameter method to polymer containing solely phenolic and acrylate repeat units.

22. The photoresist of claim 21 wherein the one or more photoacid generator compounds are present in a concentration of at least about 5 weight percent.

23. The photoresist of claims 20 or 21 wherein the one or more photoacid generator compounds are present in a concentration of at least about 8 weight percent based on weight of total solids of the photoresist composition.

24. The photoresist of claims 20 or 21 wherein the one or more photoacid generator compounds are present in a concentration of at least about 10 percent based on weight of total solids of the photoresist composition.

25. The photoresist of claims 20 or 21 wherein the one or more photoacid generator compounds are present in a concentration of no more than about 12 percent based on weight of total solids of the photoresist composition.

26. The photoresist of claims 20 or 21 wherein the one or more photoacid generator compounds are present in a concentration of from about 10 to about 15 weight percent of total solids of the photoresist composition.

27. The photoresist of any one of claims 20 through 26 wherein the one or more photoacid generator compounds are ionic compounds.

28. The photoresist of any one of claims 20 through 27 wherein the one or more photoacid generator compounds are non-ionic compounds.

29. The photoresist of any one of claims 20 through 26 wherein the one or more photoacid generator compounds are onium compounds, imidosulfonate compounds, N-sulfonyloxyimide compounds, sulfonate ester compounds, nitrobenzyl compounds, disulfone compounds, and/or halogenated non-ionic compounds, or mixtures thereof.

30. The photoresist of any one of claims 20 through 29 wherein the one or more photoacid generator compounds produce a halo-alkyl sulfonic acid upon exposure to activating radiation.

31. The photoresist of any one of claims 20 through 29 wherein the one or more photoacid generator compounds produce a per-fluoro sulfonic acid upon exposure to activating radiation.

32. The photoresist of any one of claims 20 through 31 wherein the resin comprises a polymer that contains phenolic units.

33. The photoresist of any one of claims 20 through 31 wherein the resin comprises a polymer that contains phenolic and photoacid-labile alkyl acrylate units.

34. The photoresist of any one of claims 20 through 31 wherein the resin comprises a polymer that contains 1) phenolic units, 2) phenyl units, and 3) photoacid-labile alkyl acrylate units.

35. The photoresist of any one of claims 20 through 34 wherein the resin comprises a polymer that contains acetal, ketal or ortho ester groups.

35. A negative photoresist composition comprising a resin and one or more photoacid generator compounds, wherein the one or more photoacid generator compounds are present in a concentration of at least about 5 weight percent based on weight of total solids of the photoresist composition, and the photoresist is imageable. with radiation having a wavelength of less than about 160 nm, or electron beam or ion beam radiation.

36. The photoresist of claim 35 wherein the one or more photoacid generator compounds are present in a concentration of at least about 6, 7, 8, 9, 10, 11 or 12 weight percent based on weight of total solids of the photoresist composition.

37. An article of manufacture comprising as substrate having coated thereon a photoresist composition of any one of claims 20 through 36.

38. The article of claim 37 wherein the substrate is a microelectronic wafer substrate.

39. The article of claim 37 or 38 wherein the photoresist coating has been imaged with radiation having a wavelength of less than about 160 nm, or electron beam or ion beam radiation.
